(19) United States
(12) Patent Application Publication
(10) Pub. No.: US 2024/0074041 A1
(43) Pub. Date: Feb. 29, 2024

(54) CIRCUIT BOARD

(71) Applicant: CHIPBOND TECHNOLOGY CORPORATION, Hsinchu (TW)

(72) Inventors: Gwo-Shyan Sheu, Kaohsiung City (TW); Kuo-Liang Huang, Kaohsiung City (TW); Hsin-Hao Huang, Kaohsiung City (TW); Pei-Wen Wang, Taichung City (TW); Yu-Chen Ma, Kaohsiung City (TW)

(21) Appl. No.: 18/234,642

(22) Filed: Aug. 16, 2023

(30) Foreign Application Priority Data
Aug. 25, 2022 (TW) 111209230

(51) Int. Cl. H05K 1/02; H05K 1/11

(52) U.S. Cl. CPC H05K 1/0268; H05K 1/111

(57) ABSTRACT

A circuit board includes a substrate and a metallic layer. A first area and at least one second area are defined on a portion of the substrate, the second area is located outside the first area. The metallic layer includes first test lines disposed on the first area and second test lines disposed on the second area. A first test pad of each of the first test lines has a first width, and a second test pad of each of the second test lines has a second width. The second width is greater than the first width such that probes of an electrical testing tool can contact the first and second test pads on the circuit board correctly during electrical testing.

### FIELD OF THE INVENTION

This invention relates to a circuit board, and more particularly to a circuit board which includes test pads having different widths.

### BACKGROUND OF THE INVENTION

As shown in FIGS. 1 and 2, a conventional circuit board 10 includes a substrate 11 and circuit lines 12 which are arranged on the substrate 11 and each has a test pad 12a. A semiconductor package can be obtained after bonding a chip 20 to the circuit board 10. The conventional circuit board 10 is easy to be deformed (shrink or warpage) owing to CTE (coefficient of thermal expansion) mismatch between the substrate 11 and the circuit lines 12. For this reason, probes 31 on an electrical testing tool 30 may not contact the test pads 12a on the deformed circuit board 10 precisely, and the circuit board 10 or the semiconductor package may be regarded as defective products.

### SUMMARY

One object of the present invention is to provide a circuit board which can prevent probes of an electrical testing tool from being unable to contact test pads on the circuit board correctly during electrical testing.

A circuit board of the present invention includes a substrate and a metallic layer. The substrate includes a first portion and a second portion in a first direction of transporting the substrate. A first area and at least one second area are defined on the second portion of the substrate, and the second area is located outside the first area in a second direction intersecting with the first direction. The metallic layer includes circuit lines, first test lines and second test lines. The circuit lines are arranged on the first portion, the first test lines are arranged on the first area of the second portion, and the second test lines are arranged on the second area of the second portion. The first and second test lines are connected to the circuit lines. Each of the first test lines includes a first test pad and each of the second test lines includes a second test pad, an imaginary line passes through the first and second test pads in the second direction. The first test pad has a first width and the second test pad has a second width in a direction of the imaginary line, and the second width is greater than the first width.

Owing to the second test pads on the second area are wider than the first test pads on the first area, the present invention can help probes of an electrical testing tool to contact the first and second test pads correctly during electrical testing. Consequently, the circuit board, a chip bonded to the circuit lines or the bonding of the chip and the circuit lines will not be considered to be defective due to testing error.

### DESCRIPTION OF THE DRAWINGS

FIG. 1 is a top view diagram illustrating a conventional circuit board.

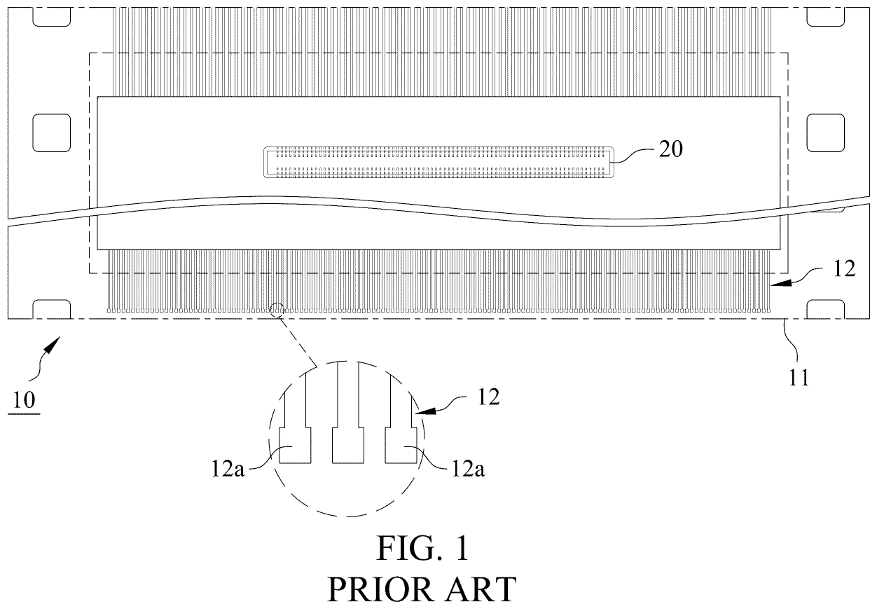

FIG. 2 is a cross-section view diagram illustrating a conventional circuit board in an electronical testing.

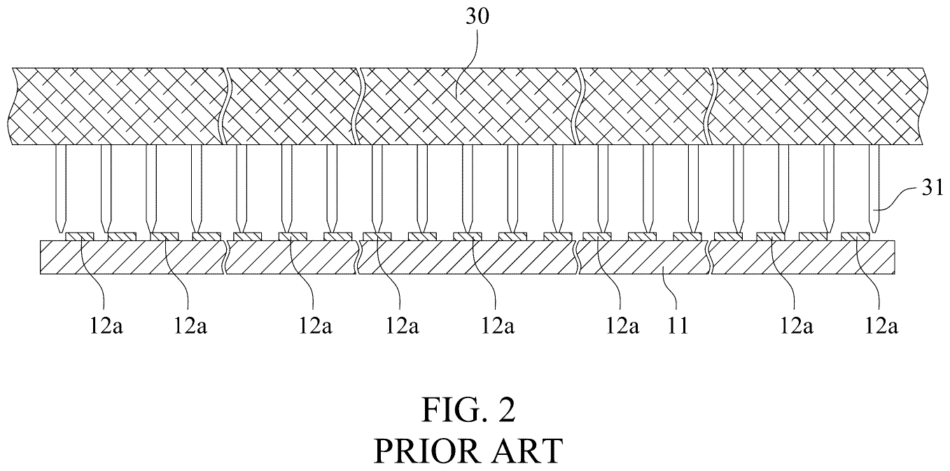

FIG. 3 is a top view diagram illustrating a circuit board in accordance with one embodiment of the present invention.

FIG. 4 is a top view diagram illustrating first test lines on a circuit board in accordance with one embodiment of the present invention.

FIG. 5 is a top view diagram illustrating second test lines on a circuit board in accordance with one embodiment of the present invention.

FIG. 6 is a cross-section view diagram illustrating a circuit board in an electrical testing in accordance with one embodiment of the present invention.

### DETAILED DESCRIPTION OF THE INVENTION

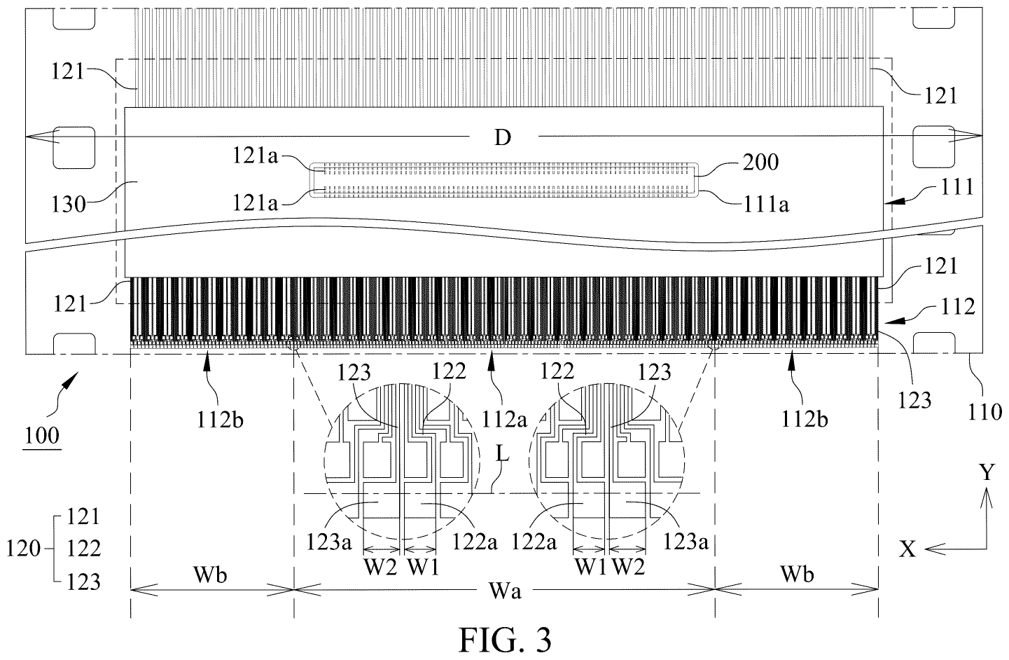

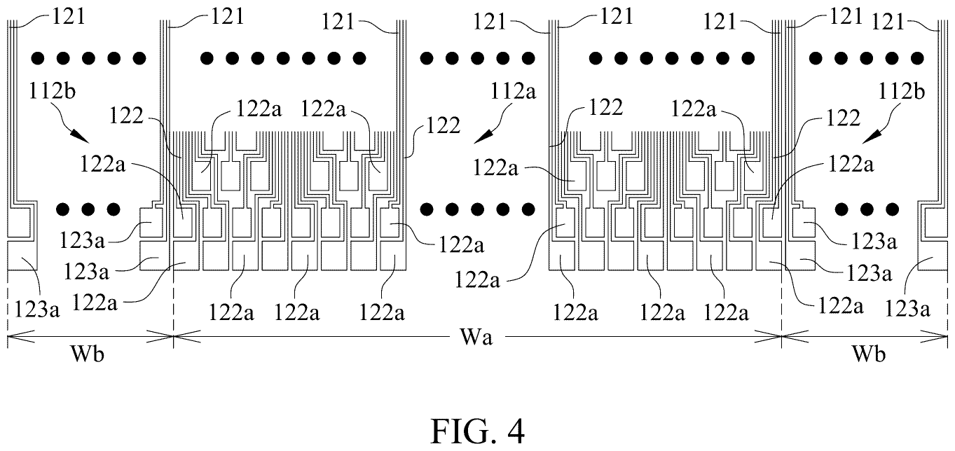

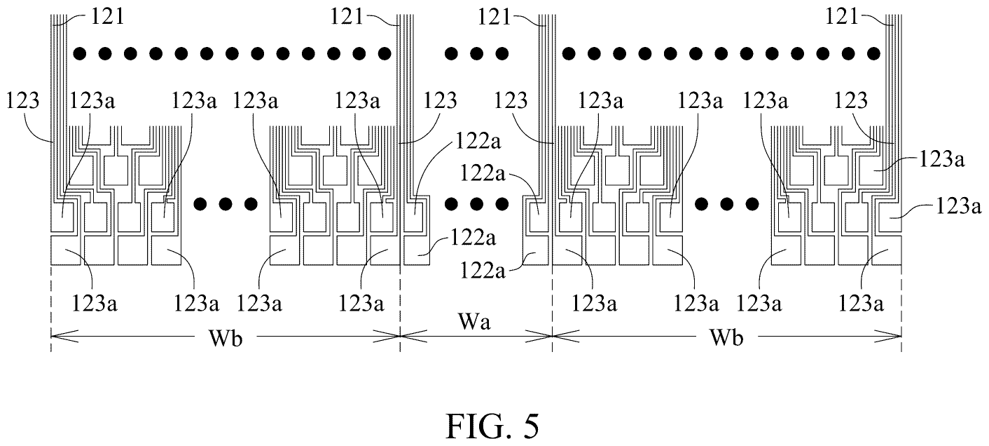

With reference to FIGS. 3 to 5, a circuit board 100 in accordance with one embodiment of the present invention includes a substrate 110, a metallic layer 120 provided on the substrate 110 and a protective layer 130. The substrate 110 may be a flexible substrate or a flexible tape, and it can be transported for processes of metallic layer patterning, chip bonding and electrical testing and can be coiled on a roll (not shown). Along a first direction Y of transporting the substrate 110, the substrate 110 is divided into a first portion 111 and a second portion 112 adjacent to the first portion 111. In this embodiment, a chip mounting area 111a is defined on the first portion 111, and a first area 112a and at least one second area 112b are defined on the second portion 112, the second area 112b is located outside the first area 112a in a second direction X intersecting with the first direction Y.

With reference to FIGS. 3 to 5, there are two second areas 112b, but not limit to, defined on the second portion 112 of the substrate 110, and the first area 112a is located between the two second areas 112b. In the second direction X, the first area 112a has a first accommodation width Wa and the second area 112b has a second accommodation width Wb, and a ratio Wb/Wa of the second accommodation width Wb to the first accommodation width Wa is between 0.19 and 1.17. Preferably, the ratio Wb/Wa is between 0.19 and 0.26 as the substrate 110 has a width D of 35 mm in the second direction X, the ratio Wb/Wa is between 0.50 and 0.61 as the substrate 110 has a width D of 48 mm in the second direction X, and the ratio Wb/Wa is between 1.01 and 1.17 as the substrate 110 has a width D of 70 mm in the second direction X. With reference to FIGS. 3 to 5, the patterned metallic layer 120 includes circuit lines 121, first test lines 122 and second test lines 123. The circuit lines 121 are arranged on the first portion 111 of the substrate 110, each of the circuit lines 121 has at least one inner lead 121a which is located on the chip mounting area 111a and provided to be bonded to a chip 200. The first test lines 122 are arranged on the first area 112a of the second portion 112 of the substrate 110, the second test lines 123 are arranged on the second area 112b of the second portion 112 of the substrate 110, and the first test lines 122 and the second test lines 123 are connected to the circuit lines 121, respectively. The protective layer 130 covers the circuit lines 121, but not cover the inner lead 121a of each of the circuit lines 121, the first test lines 122 and the second test lines 123.

With reference to FIGS. 3 to 5, each of the first test lines 122 has a first test pad 122a, and each of the second test lines 123 has a second test pad 123a. An imaginary line L passes through the first test pad 122a and the second test pad 123a along the second direction X. In the direction of the imaginary line L, a distance between the two outermost first test pads 122a is defined as the first accommodation width Wa of the first area 112a, and a distance between the second test pad 123 which is most adjacent to the first area 112a and the outermost second test pad 123 is defined as the second accommodation width Wb of the second area 112b.

With reference to FIGS. 3 to 5, a second width W2 of the second test pad 123a is greater than a first width W1 of the first test pad 122a. And preferably, a difference between the second width W2 and the first width W1 is less than or equal to 5 μm.

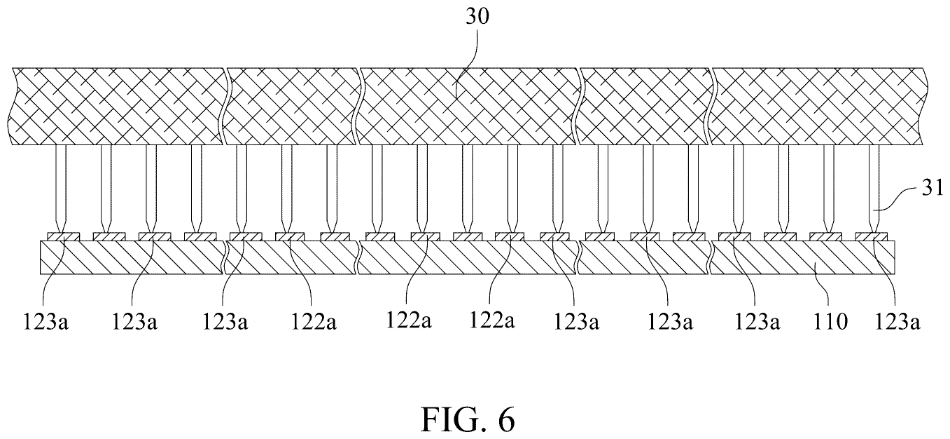

With reference to FIG. 6, the circuit board 100 may be deformed because of CTE (coefficient of thermal expansion) mismatch between the substrate 110 and the metallic layer 120, however, the present invention can help probes 31 of an electrical tool 30 to contact the first test pads 122a and the second test pads 123a correctly owing to the second test pads 123a on the second area 112b are designed to be wider than the first test pads 122a on the first area 112a. As a result, the circuit board 100, the chip 200 bonded to inner leads 121a of the circuit lines 121 or the bonding of the chip 200 and the inner leads 121a will not be considered to be defective due to testing error.

While this invention has been particularly illustrated and described in detail with respect to the preferred embodiments thereof, it will be clearly understood by those skilled in the art that is not limited to the specific features shown and described and various modified and changed in form and details may be made without departing from the scope of the claims.

What is claimed is:

1. A circuit board comprising:
a substrate including a first portion and a second portion in a first direction of transporting the substrate, a first area and at least one second area are defined on the second portion, and the at least one second area is located outside the first area in a second direction intersecting with the first direction; and
a metallic layer including a plurality of circuit lines, a plurality of first test lines and a plurality of second test lines, the plurality of circuit lines are disposed on the first portion of the substrate, the plurality of first test lines are disposed on the first area of the second portion of the substrate, the plurality of second test lines are disposed on the at least one second area of the second portion of the substrate, each of the plurality of first test lines is connected to one of the plurality of circuit lines and includes a first test pad, each of the plurality of second test lines is connected to one of the plurality of circuit lines and includes a second test pad, the first and second test pads are configured to be passed through by an imaginary line along the second direction, wherein the first test pad has a first width and the second test pad has a second width in a direction of the imaginary line, and the second width is greater than the first width.

2. The circuit board in accordance with claim 1, wherein the first area has a first accommodation width and the at least one second area has a second accommodation width in the second direction, a ratio of the second accommodation width to the first accommodation width is between 0.19 and 1.17.

3. The circuit board in accordance with claim 2, wherein the ratio of the second accommodation width to the first accommodation width is between 0.19 and 0.26.

4. The circuit board in accordance with claim 2, wherein the ratio of the second accommodation width to the first accommodation width is between 0.50 and 0.61.

5. The circuit board in accordance with claim 2, wherein the ratio of the second accommodation width to the first accommodation width is between 1.01 and 1.17.

6. The circuit board in accordance with claim 2, wherein a distance between the two outermost first test pads is defined as the first accommodation width of the first area, and a distance from the second test pad which is adjacent to the first area to the outermost second test pad is defined as the second accommodation width of the at least one second area.

7. The circuit board in accordance with claim 1, wherein a difference between the second width and the first width is less than or equal to 5 μm.

8. The circuit board in accordance with claim 2, wherein a difference between the second width and the first width is less than or equal to 5 μm.

9. The circuit board in accordance with claim 3, wherein a difference between the second width and the first width is less than or equal to 5 μm.

10. The circuit board in accordance with claim 4, wherein a difference between the second width and the first width is less than or equal to 5 μm.

11. The circuit board in accordance with claim 5, wherein a difference between the second width and the first width is less than or equal to 5 μm.

12. The circuit board in accordance with claim 6, wherein a difference between the second width and the first width is less than or equal to 5 μm.
